(19) United States
(12) Patent Application Publication
(10) Pub. No.: US 2011/0193848 A1
(43) Pub. Date: Aug. 11, 2011

(54) LEVEL SHIFTER CIRCUIT, LOAD DRIVE DEVICE, AND LIQUID CRYSTAL DISPLAY DEVICE

(75) Inventor: Hidekazu Kojima, Kyoto (JP)

(73) Assignee: ROHM CO., LTD., Kyoto (JP)

(21) Appl. No.: 13/125,068

(22) PCT Filed: Oct. 29, 2009
(86) PCT No.: PCT/JP2009/068556

§ 371 Date: Apr. 20, 2011

(30) Foreign Application Priority Data
Oct. 30, 2008 (JP) 2008-279801

(51) Int. Cl. G09G 3/36; H03L 5/00; H03K 3/00; G06F 3/038

(52) U.S. Cl. 345/211; 327/333; 327/108; 345/98

(57) ABSTRACT

The level shifter circuit includes a differential amp (2) that uses a differential input stage made of a pair of N-channel field effect transistors (N1) and (N2) that are connected between the application terminal of a ground potential VSS and the application terminal of a load potential MVDD, receives in a differential mode an input signal IN that is pulse-driven between the ground potential VSS and a positive potential VDDI, and by differential amplification thereof, generates an output signal OUT that is pulse-driven between the ground potential VSS and the load potential MVDD.

### TECHNICAL FIELD

The present invention relates to a level shifter circuit, a load drive device (e.g., a liquid crystal drive device) and a liquid crystal display device that use the level shifter circuit.

### BACKGROUND ART

FIG. 6 is a circuit diagram that shows a conventional example of a level shifter circuit. As shown in FIG. 6, the conventional level shifter circuit is so structured as to include: inverters INVa, INVb; P-channel MOS field effect transistors Pa to Pd; and N-channel MOS field effect transistors Na to Nd. Here, in the level shifter circuit having the above structure, each of the inverters INVa, INVb is connected between an application terminal of a positive potential VDDI (e.g., 1.6 [V]) and an application terminal of a ground potential VSS (e.g., 0 [V]); each of the transistors Pa, Pb, Na, and Nb is connected between the application terminal of the positive potential VDDI and an application terminal of a negative potential MVDD (e.g., −6.0 [V]); and each of the transistors Pc, Pd, Nc, and Nd is connected between the application terminal of the ground potential VSS and the application terminal of the negative potential MVDD.

Here, as an example of a conventional technology relating to the above description, it is possible to list a patent document 1.

### CITATION LIST

### Patent Literature

Patent document 1: JP-A-2000-195284

### SUMMARY OF INVENTION

### Technical Problem

Indeed, according to the above conventional level shifter circuit, it is possible to convert an input signal IN pulse-driven between the ground potential VSS and the positive potential VDDI into an output signal OUT pulse-driven between the ground potential and the negative potential MVDD and output the output signal.

However, the conventional level shifter circuit is so structured as to receive the input signal IN pulse-driven between the ground potential VSS and the positive potential VDDI by means of gates of the P-channel MOS field effect transistors Pa, and Pb, so that to surely turn on/off the transistors Pa, and Pb, it is necessary to apply the positive potential VDDI to sources of the transistors Pa, and Pb instead of applying the ground potential VSS.

As described above, in the conventional level shifter circuit in which the positive potential VDDI is applied to the sources of the transistors Pa, and Pb, as a maximum potential, a potential difference (e.g, 7.6 [V]) between the positive potential VDDI and the negative potential MVDD is applied across the gates and the sources of the transistors Pa to Pc and of the transistors Na to Nc, between the gates and the drains of the transistors Pa to Pc and of the transistors Na to Nc, or between the sources and the drains of the transistors Pa to Pc and of the transistors Na to Nc, so that as these transistors Pa to Pc and transistors Na to Nc, it is necessary to use high breakdown-voltage elements (e.g., a breakdown voltage of 28 [V]) that are able to endure the above potential difference.

However, the above high breakdown-voltage elements have a large gate capacitance compared with an intermediate breakdown-voltage element (e.g, 6 [V]) and a low breakdown-voltage element (e.g., 1.8 [V]) that have a lower breakdown voltage; and needs many currents for charging and discharging, which is a cause that brings a drop in an on/off response speed and an increase in a through-type current (and an increase in an operation current consumed by the entire level shifter circuit).

Besides, the above high breakdown-voltage element has a large layout area compared with the intermediate breakdown-voltage element and the low breakdown-voltage element, which is a cause that is detrimental to size reduction of a semiconductor device. Especially, like a liquid crystal diver IC, in a case where a plurality of level shifter circuits have to be confined and disposed into a width-wise length of a liquid crystal panel, it is impossible to enlarge the level shifter circuit in a width direction (long-edge direction) because of a constraint on a PAD pitch and the like, so that to secure the layout area, there is no other choice but to enlarge the level shifter circuit in a longitudinal direction (short-edge direction) and it is hard to meet a requirement for narrow framing of the liquid crystal panel.

In light of the above problems, it is an object of the present invention to provide a level shifter circuit that curbs the number of high breakdown-voltage elements utilized as small as possible, allows reduction in the power consumption and increase in the response speed, and reduction in the layout area; a load drive device and a liquid crystal display device that use the level shifter circuit.

### Solution to Problem

To achieve the above object, a level shifter circuit according to the present invention is so structured (first structure) as to include a differential amplifier that by using a differential input stage which includes a pair of N-channel field effect transistors connected between an application terminal of a ground potential and an application terminal of a negative potential, receives, in a differential way, an input signal that is pulse-driven between the ground potential and a positive potential, and applies differential amplification to the input signal, thereby generating an output signal that is pulse-driven between the ground potential and the negative potential.

Here, in the level shifter circuit having the first structure, it is preferable to employ a structure (second structure) in which of a plurality of transistors that form the level shifter circuit, the pair of N-channel field effect transistors that form the differential input stage are high breakdown-voltage elements that are able to endure a potential difference between the positive potential and the negative potential; and the other transistors are intermediate breakdown-voltage elements and low breakdown-voltage elements that have a lower breakdown voltage.

Besides, it is preferable that the level shifter circuit having the second structure is so structured (third structure) as to include: an enable control portion that turns on/off the differential amplifier in accordance with a first control signal; and a latch output portion that sample-holds the output signal of the differential amplifier in accordance with a second control signal.

Besides, a load drive device according to the present invention is a load drive device that is so structured (fourth structure) as to include n (n is 1 or a larger integer number) sets of units each of which has: m level shifter circuits that perform level shifting of each of m-system (m is 2 or a larger integer number) input signals to generate m-system output signals; a digital/analog conversion circuit that receives the m-system output signals as an m-bit digital signal, converts the m-bit digital signal into an analog signal and output the analog signal; and an amplifier circuit that supplies the analog signal as a load drive signal to the load; wherein of the plurality of level shifter circuits, a level shifter circuit that converts an input signal pulse-driven between a ground potential and a positive potential into an output signal pulse-driven between the ground potential and a negative potential is the level shifter circuit having the third structure.

Here, it is preferable that the load drive device having the fourth structure is so structured (fifth structure) as to include: a shared level shifter circuit that generates first and second control signals that are pulse-driven between the ground potential and the negative potential; and outputs these signals to the plurality of level shifter circuits.

Besides, in the load drive device having the fifth structure, it is preferable to employ a structure (sixth structure) in which the load is a liquid crystal pixel.

Besides, a liquid crystal display device according to the present invention is so structured (seventh structure) as to include: the load drive device having the sixth structure; and the liquid crystal pixel driven by the load drive device.

Besides, it is preferable that the liquid crystal display device having the seventh structure is so structured (eighth structure) as to include a multiplexer that by distributing each of n-system output signals output from the load drive device to z systems (z is 1 or a larger integer number), generates (n×z)-system output signals and supplies these signals to the liquid crystal pixel.

Besides, in the liquid crystal display device having the eighth structure, it is preferable to employ a structure (ninth structure) in which the load drive device includes a multiplexer timing generator that performs timing control of the multiplexer in accordance with generation operation of the n-system output signals.

### Advantageous Effects of Invention

In the level shifter circuit according to the present invention and the load drive device having the level shifter circuit, it becomes possible to curb the number of high breakdown-voltage elements utilized as small as possible, achieve reduction in the power consumption, increase in the response speed, and reduction in the layout area.

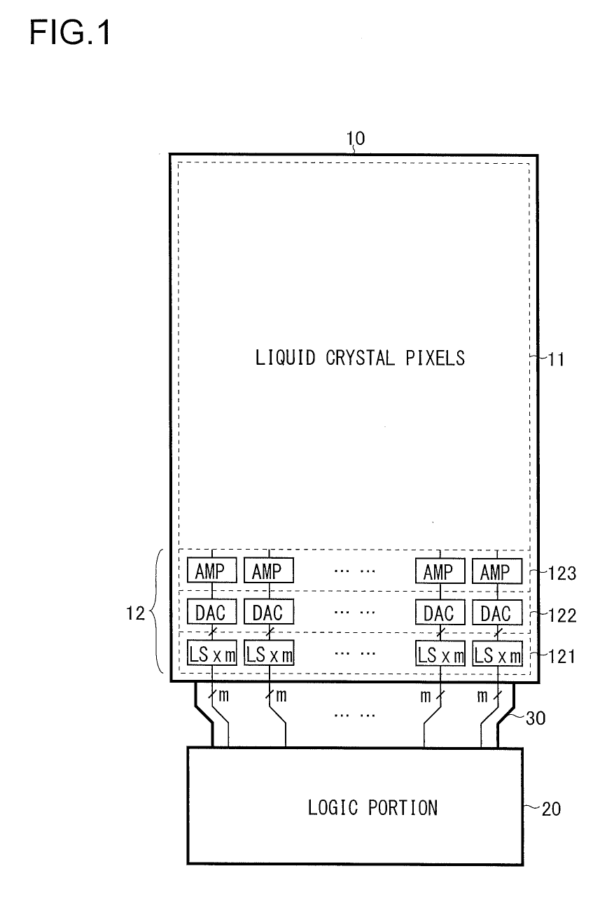

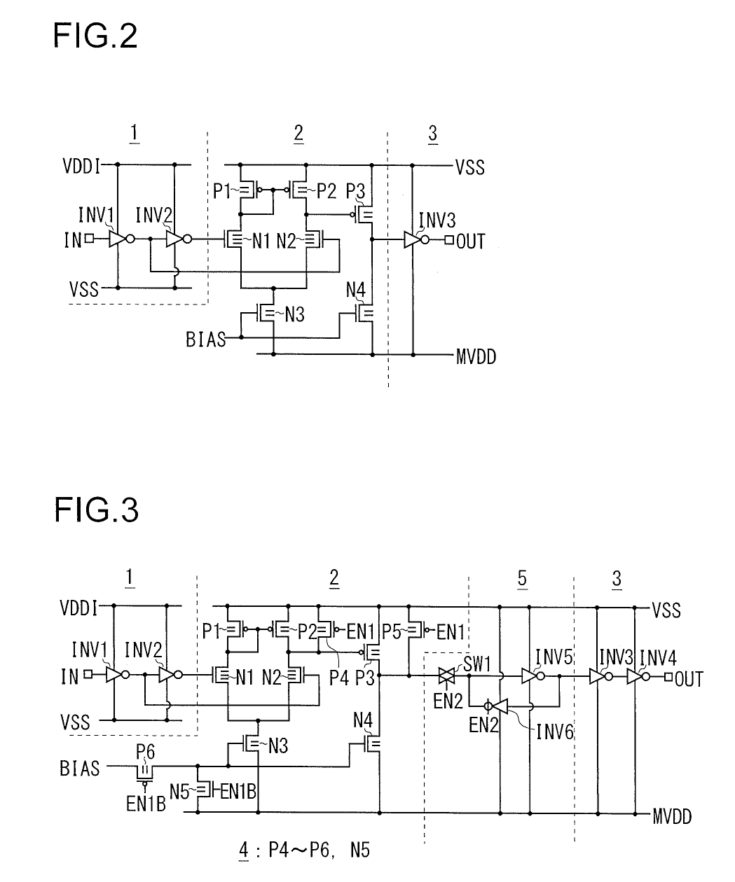

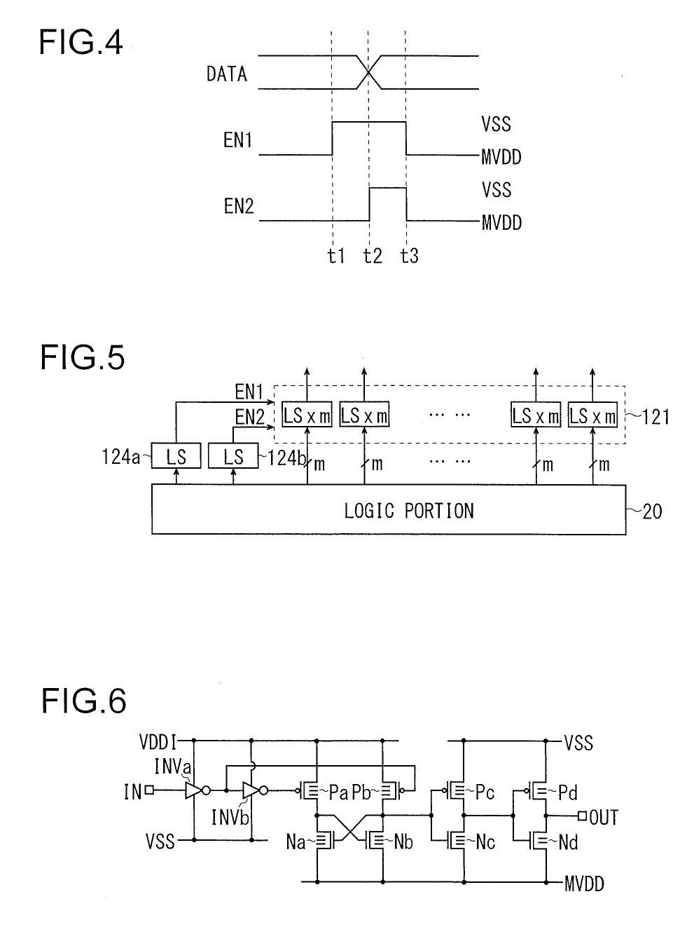

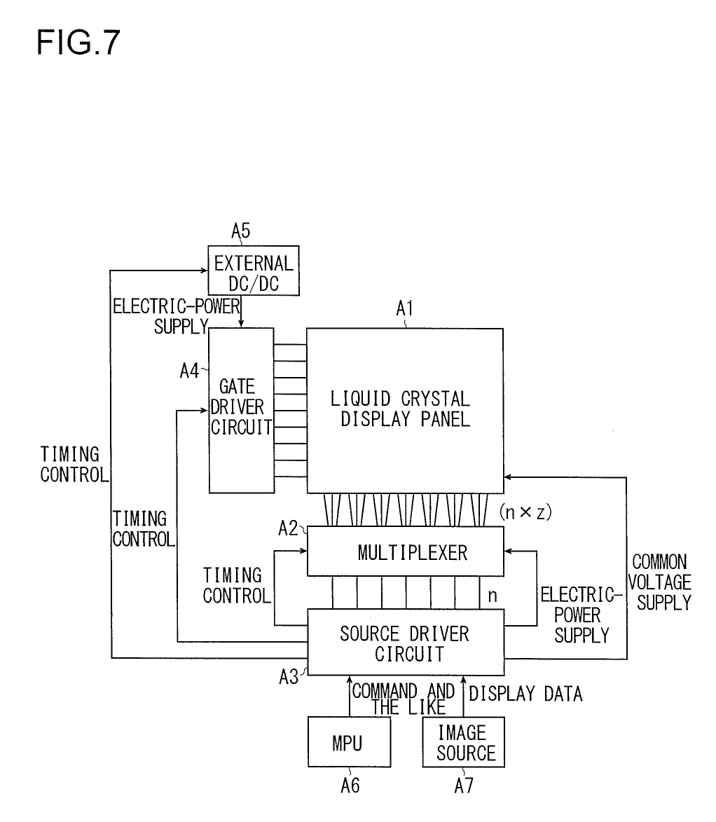

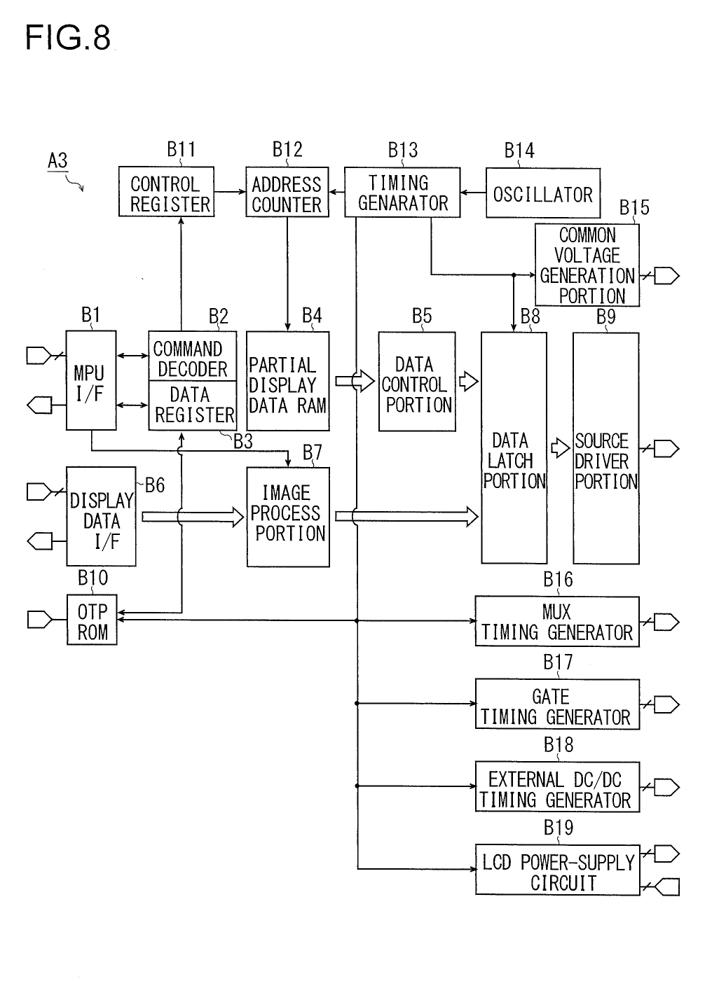

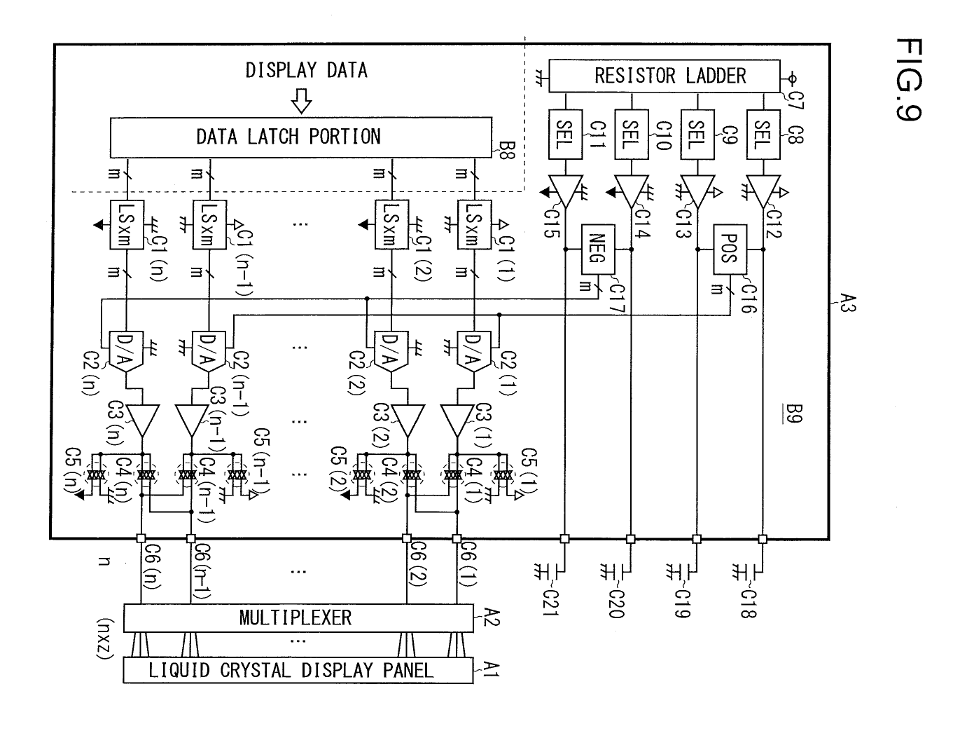

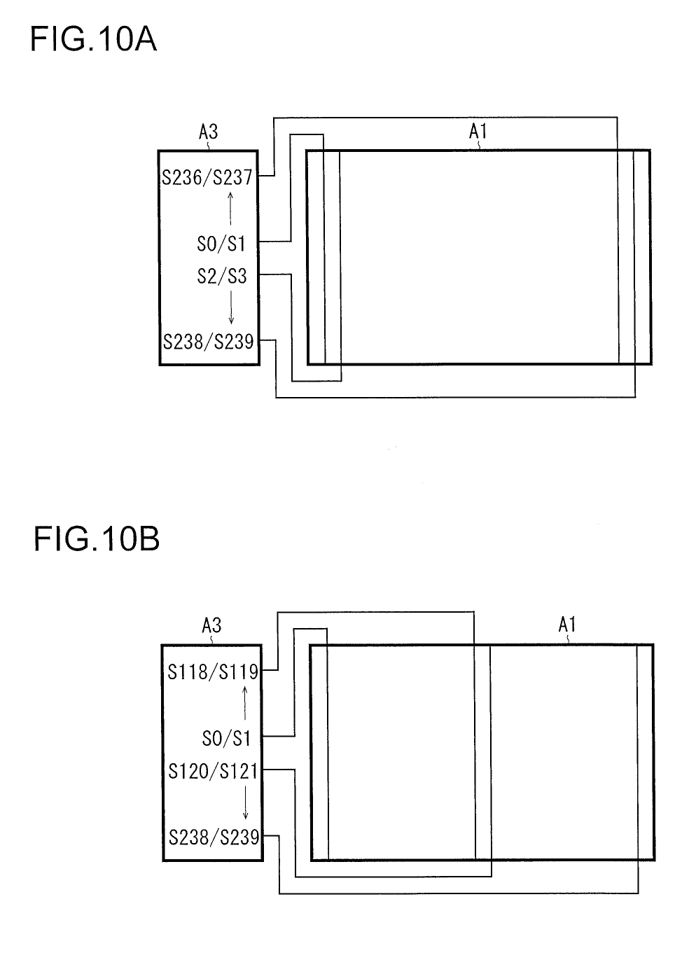

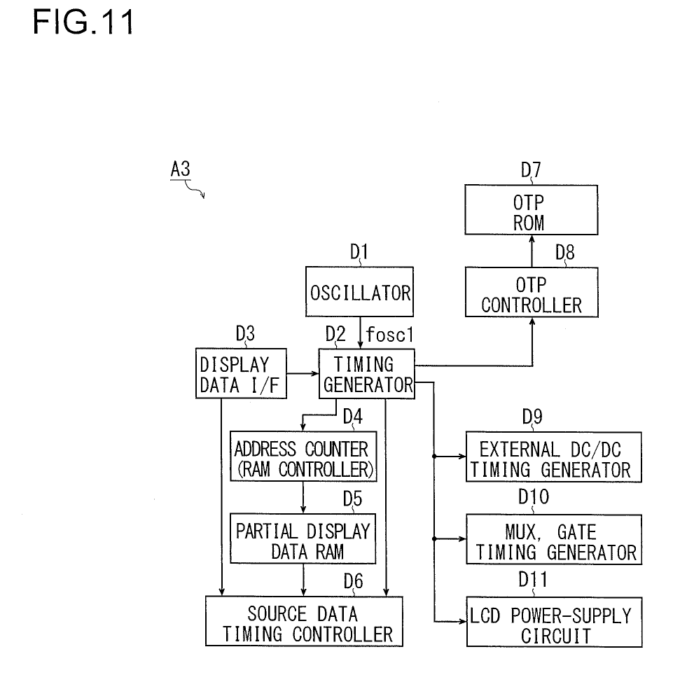

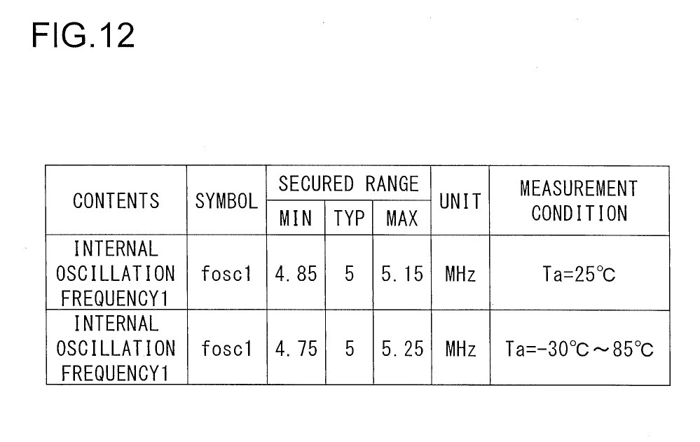

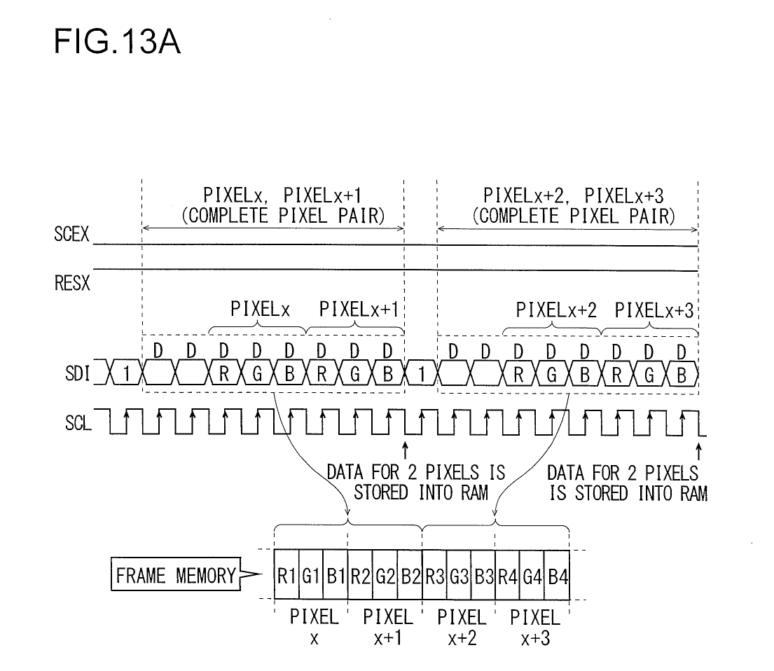

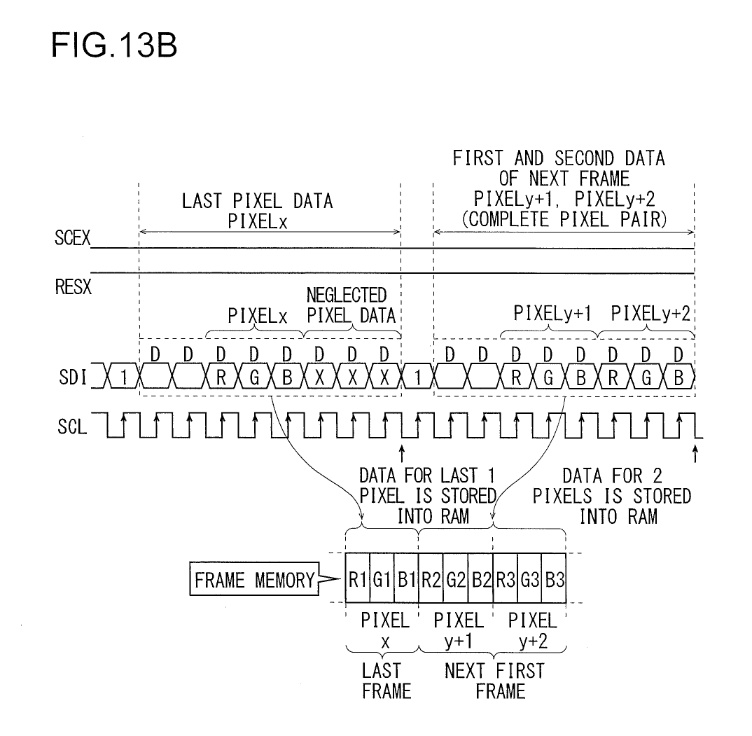

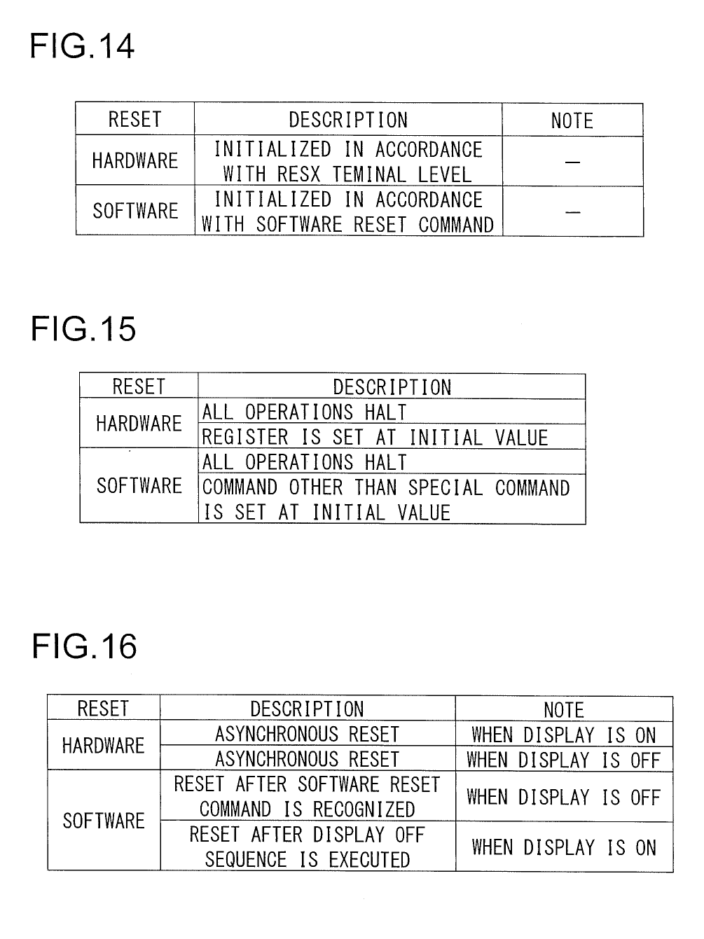

### BRIEF DESCRIPTION OF DRAWINGS

[FIG. 1] is a schematic diagram showing a first structural example of a liquid crystal display device that uses a level shifter circuit according to the present invention.

[FIG. 2] is a circuit diagram showing a first embodiment of a level shifter circuit according to the present invention.

[FIG. 3] is a circuit diagram showing a second embodiment of a level shifter circuit according to the present invention.

[FIG. 4] is a timing chart showing an example of an amplifier enable signal EN1 and a latch enable signal EN2.

[FIG. 5] is a block diagram showing a disposition example of a shared level shifter circuit.

[FIG. 6] is a circuit diagram showing a conventional example of a level shifter circuit.

[FIG. 7] is a block diagram showing a second structural example of a liquid crystal display device that uses a level shifter circuit according to the present invention.

[FIG. 8] is a block diagram showing a structural example of a source driver circuit A3.

[FIG. 9] is a block diagram showing a structural example of a source driver portion B9.

[FIG. 10A] is a schematic diagram showing a first connection outlook of a liquid crystal display panel A1 and the source driver circuit A3.

[FIG. 10B] is a schematic diagram showing a second connection outlook of the liquid crystal display panel A1 and the source driver circuit A3.

[FIG. 11] is a block diagram for describing timing control of the source driver circuit A3.

[FIG. 12] is a table showing an example of an oscillation characteristic.

[FIG. 13A] is a timing chart showing a first operation example of an 8-color display mode.

[FIG. 13B] is a timing chart showing a second operation example of the 8-color display mode.

[FIG. 14] is a table for describing a reset method.

[FIG. 15] is a table for describing a state after a reset.

[FIG. 16] is a table for describing an automatic display off sequence.

### DESCRIPTION OF EMBODIMENTS

Hereinafter, detailed description of an example of a liquid crystal display device that uses a level shifter circuit according to the present invention.

FIG. 1 is a schematic diagram showing a first structural example of a liquid crystal display device that uses a level shifter circuit according to the present invention. As shown in FIG. 1, the liquid crystal display device in the present example has: a glass board 10; a logic portion 20; and a flexible cable 30.

On the glass board 10, a liquid crystal pixel 11 is formed; besides, on a marginal region (frame region), a liquid crystal drive device 12 (liquid crystal driver IC) is directly mounted in a COG (Chip On Glass) way.

The liquid crystal drive device 12, as a means for driving the liquid crystal pixel 11, has: a source driver portion; a gate driver portion; and a common driver portion; especially, the source driver portion of the liquid crystal drive device 12, as shown in FIG. 1, has: a level shifter circuit group 121; a digital/analog conversion circuit group 122; and a source amplifier group 123.

More specifically, the source driver portion of the liquid crystal drive device 12 has n sets (where n is 1 or a larger integer number) of units, each of which includes: m level shifter circuits (in the example shown in FIG. 1, represented as single block elements indicated by a reference sign “LS×m”) that perform level shifting of each of m-system (where m is 2 or a larger integer number) input signals to generate m-system output signals; digital/analog conversion circuits (in the example shown in FIG. 1, represented as block elements indicated by a reference sign “DAC”) that receive the m-system output signals as m-bit digital signals, convert them into analog signals and output them; and source amplifier circuits (in the example shown in FIG. 1, represented as block elements indicated by a reference sign “AMP”) that supply the analog signals as source signals to the liquid crystal pixel 11.

Here, as for the source signal that is supplied to the liquid crystal pixel 11 as a liquid crystal drive signal, from the viewpoint for preventing the sticking of the liquid crystal pixel 11, it is desirable that the polarity is inversed from positive to negative and vice versa for every predetermined frame. Accordingly, in the liquid crystal drive device 12 according to the present embodiment, a structure is employed, in which a first drive system (a positive-polarity level shifter circuit, a positive-polarity digital/analog conversion circuit, and a positive-polarity source amplifier circuit) generates a positive-polarity source signal in accordance with an input signal (image signal) from the logic portion 20, and a second drive system (a negative-polarity level shifter circuit, a negative-polarity digital/analog conversion circuit, and a negative-polarity source amplifier circuit) that generates a negative-polarity source signal in accordance with the input signal from the logic portion 20 are separately prepared; and the liquid crystal pixel 11 is driven by alternately switching both systems. Here, the level shifter circuit according to the present invention is suitably used as the above negative-polarity level shifter circuit; its structure is described in detail later.

The logic portion 20 is connected to the liquid crystal drive device 12 on the glass board 10 via a flexible cable 30; and outputs control signals (a source signal, a gate signal, a common signal) for the liquid crystal pixel 11 via the liquid crystal drive device 12.

The flexible cable 30 is a signal transmission route that is formed by disposing a printed wiring on a thin film which has flexibility; and at both ends thereof, connectors for securing an electric connection with the liquid crystal drive device 12 and the logic portion 20 are disposed. Here, in the example shown in FIG. 1, the structure in which the liquid crystal drive device 12 is mounted on the glass board 10 in the COG way is described; however, the structure of the present invention is not limited to this, and the liquid crystal drive device 12 may be mounted on the flexible cable 30 in a COF (Chip On Film) way.

FIG. 2 is a circuit diagram showing a first embodiment of the level shifter circuit according to the present invention. As shown in FIG. 2, the level shifter circuit according to the present embodiment is a means that converts an input signal IN (image signal from the logic portion 20) pulse-driven between a ground potential VSS (0 [V]) and a positive potential VDDI (e.g., 1.6 [V]) into an output signal OUT pulse-driven between the ground potential VSS and a negative potential MVDD (e.g., −6.0 [V]); and has: an input buffer 1; a differential amplifier 2; an output buffer 3. The input buffer 1 has inverters INV1, INV2. The differential amplifier 2 has: P-channel MOS field effect transistors P1 to P3; and N-channel MOS field effect transistors N1 to N4. The output buffer 3 has an inverter INV3.

An application terminal of the inverter INV1 is connected to an application terminal of the input signal IN. An application terminal of the INV2 is connected to an output terminal of the inverter INV1. First power-supply terminals of the inverters INV1, INV2 both are connected to an application terminal of the positive potential VDDI. Second power-supply terminals of the inverters INV1, INV2 both are connected to an application terminal of the ground potential VSS. Sources of the transistors P1, P2 both are connected to the application terminal of the ground potential VSS. Gates of the transistors Pa, P2 both are connected to a drain of the transistor P1. Drains of the transistors N1, N2 both are connected to the drains of the transistors P1, P2. A gate of the transistor N1 is connected to an output terminal of the INV2. A gate of the transistor N2 is connected to an output terminal of the inverter INV1. Sources of the transistors N1, N2 both are connected to a drain of the transistor N3. A gate of the transistor N3 is connected to an application terminal of a bias potential BIAS. The drain of the transistor N3 is connected to an application terminal of the negative potential MVDD. A source of the transistor P3 is connected to the application terminal of the ground potential VSS. A gate of the transistor P3 is connected to the drain of the transistor P2. A drain of the transistor P3 is connected to a drain of the transistor N4. A gate of the transistor N4 is connected to the application terminal of the bias potential BIAS. A source of the transistor N4 is connected to the application terminal of the negative potential MVDD. An input terminal of the inverter INV3 is connected to the drain of the transistor P3. An output terminal of the inverter INV3 is connected to an output terminal of the output signal OUT. A first power-supply terminal of the inverter INV3 is connected to the application terminal of the ground potential VSS. A second power-supply terminal of the inverter INV3 is connected to the application terminal of the negative potential MVDD.

Next, operation of the level shifter circuit having the above structure is described. In the level shifter circuit having the above structure, when the input signal IN is at a high level (VDDI), the high level (VDDI) is applied to the gate of the transistor N1 and a low level (VSS) is applied to the gate of the transistor N2, so that a current flowing into the transistor N1 increases and a current flowing into the transistor N2 decreases. As a result of this, a gate potential of the transistor P3 increases and a drain potential (output level of the differential amplifier 2) of the transistor P3 decreases. Accordingly, the final output signal OUT that is output via the inverter INV3 goes to the high level. In contrast, when the input signal IN is at the low level (VSS), the low level (VSS) is applied to the gate of the transistor N1 and the high level (VDDI) is applied to the gate of the transistor N2, so that the current flowing into the transistor N1 decreases and the current flowing into the transistor N2 increases. As a result of this, the gate potential of the transistor P3 decreases and the drain potential (output level of the differential amplifier 2) of the transistor P3 increases. Accordingly, the final output signal OUT that is output via the inverter INV3 goes to the low level.

As described above, the level shifter circuit having the above structure converts the input signal IN (image signal from the logic portion 20) pulse-driven between the ground potential VSS and the positive potential VDDI into the output signal OUT pulse-driven between the ground potential VSS and the negative potential MVDD and output the output signal.

Here, in the level shifter circuit having the above structure, as a maximum potential, a potential difference (e.g., 7.6 [V]) between the positive potential VDDI and the negative potential MVDD is applied across the gate and the source of each of the transistors N1, N2 that form the differential amplifier 2 (especially, a differential input stage thereof), so that as the transistors N1, N2, it is necessary to use high breakdown-voltage elements (e.g, a breakdown voltage of 28 [V]); however, only a potential difference (eg., 6.0 [V]) between the ground potential VSS and the negative potential MVDD is applied at the most across the gate and the source, across the gate and the drain, or across the source and the drain of each of the other transistors N3, N4, P1 to P3 that form the differential amplifier 2 and of a transistor (not shown) that forms the inverter INV3, so that as these transistors, it is possible to use intermediate breakdown-voltage elements (e.g., a breakdown voltage of 6.0 [V]) that have a lower breakdown voltage.

Besides, only a potential difference (eg., 1.6 [V]) between the positive potential VDDI and the ground potential VSS is applied at the most across the gate and the source, across the gate and the drain, or across the source and the drain of each of transistors (not shown) that form the inverters INV1, INV2, so that as these transistors, it is possible to use low breakdown-voltage elements (e.g., a breakdown voltage of 1.8 [V]) that have a further lower breakdown voltage.

As described above, the level shifter circuit according to the present embodiment employs the structure to have the differential amplifier 2 which by using the differential input stage which includes the pair of N-channel field effect transistors N1, N2 that are connected between the application terminal of the ground potential VSS and the application terminal of the negative potential MVDD, receives, in a differential way, the input signal IN pulse-driven between the ground potential VSS and the positive potential VDDI and applies differential amplification to the input signal, thereby generating the output signal OUT pulse-driven between the ground potential VSS and the negative potential MVDD, so that it becomes possible to curb the number of high breakdown-voltage elements utilized as small as possible, and achieve reduction in the power consumption, increase in the response speed, and reduction in the layout area.

Especially, even in a case where like in the liquid crystal drive device 12, the many level shifter circuits have to be confined and disposed into the width-wise length of the liquid crystal panel, by using the level shifter circuit according to the present embodiment, it is possible to reduce the size of the liquid crystal drive device 12 in a longitudinal direction (short-edge direction), so that it becomes possible to achieve chip-cost reduction (e.g., about 30%) of the liquid crystal drive device 12, and further it becomes possible to meet a requirement for narrow framing of the liquid crystal panel.

FIG. 3 is a circuit diagram showing a second embodiment of the level shifter circuit according to the present invention. As shown in FIG. 3, the level shifter circuit according to the second embodiment is further improved on the basis of the above first embodiment. Accordingly, the same components as those in the first embodiment are indicated by the same reference numbers as those in FIG. 2 to skip double description; and hereinafter, description is performed focusing on components unique to the second embodiment.

As shown in FIG. 3, the level shifter circuit according to the present embodiment, besides the components in the above first embodiment, has: an enable control portion 4 that turns on/off the differential amplifier 2 in accordance with an amplifier enable signal EN1; and a latch portion 5 that sample-holds the output signal from the differential amplifier 2 in accordance with a latch enable signal EN2. The enable control portion 4 has: P-channel MOS field effect transistors P4 to P6; and an N-channel MOS field effect transistor N5. The latch portion 5 has: an inverter INV5; a 3-state inverter INV6; and a path switch SW1. Besides, an inverter INV4 is added to the output buffer 3 for the purpose of achieving logic matching of the output signal OUT.

A source of the transistor P4 is connected to the application terminal of the ground potential VSS. A gate of the transistor P4 is connected to an application terminal of the amplifier enable signal EN1. A drain of the transistor P4 is connected to the gate of the transistor P3. A source of the transistor P5 is connected to the application terminal of the ground potential VSS. A gate of the transistor P5 is connected to the application terminal of the amplifier enable signal EN1. A drain of the transistor P5 is connected to the drain of the transistor P3. The transistor P6 is inserted between the application terminal of the bias potential BIAS and the gate of each of the transistors N3, N4. A gate of the transistor P6 is connected to an application terminal of an inversion amplifier enable signal EN1B (logic inversion signal of the amplifier enable signal EN1). A drain of the transistor N5 is connected to the gates of the transistors N3, N4. A gate of the transistor N5 is connected to the application terminal of the inversion amplifier enable signal EN1B. A source of the transistor N5 is connected to the application terminal of the negative potential MVDD.

An input terminal of the inverter INV5 is connected to the drain of the transistor P3 via the path switch SW1. An output terminal of the inverter INV5 is connected to the input terminal of the inverter INV3. An input terminal of the 3-state inverter INV6 is connected to the output terminal of the inverter INV5. An output terminal of the 3-state inverter INV6 is connected to the input terminal of the inverter INV5. First power-supply terminals of the inverter INV5 and the 3-state inverter INV6 both are connected to the application terminal of the ground potential VSS. Second power-supply terminals of the inverter INV5 and the 3-state inverter INV6 both are connected to the application terminal of the negative potential MVDD. Each of control terminals of the path switch SW1 and the 3-state inverter INV6 is connected to the application terminal of the latch enable signal EN2. The inverter INV4 is inserted between an output terminal of the inverter INV3 and the output terminal of the OUT signal OUT. A first power-supply terminal of the INV4 is connected to the application terminal of the ground potential VSS. A second power-supply terminal of the inverter INV4 is connected to the application terminal of the negative potential MVDD.

Basic operation (level shift operation) of the level shifter circuit having the above structure is the same as the above first embodiment; accordingly, hereinafter, with reference to FIG. 4, enable operation of the level shifter circuit is described in detail.

FIG. 4 is a timing chart showing an example of the amplifier enable signal EN1 and the latch enable signal EN2; in order from the top, the input signal IN, the amplifier enable signal EN1, and the latch enable signal EN2 are represented.

Describing based on the example in FIG. 4, the logic portion 20, until a time t1 arrives, based on recognition that data of the input signal IN are invariable, keeps the amplifier enable signal EN1 and the latch enable signal EN2 at a low level. Here, in the enable control portion 4, the transistors P4, P5 and the transistor N5 are all turned on, and the transistor P6 is turned off, so that supply of an operation current to the differential amplifier 2 is interrupted and output logic (drain potential of the transistor P3) of the differential amplifier 2 is fixed. On the other hand, in the latch portion 5, the path switch SW1 is interrupted and the output of the 3-state inverter INV6 is permitted, which results in a state in which a loop including the inverter INV5 and the 3-state inverter INV6 is formed and the output logic of the differential amplifier 2 is latched.

When the time t1 arrives, the logic portion 20, before data update of the input signal IN, changes the amplifier enable signal EN1 only to the high level. Here, in the enable control portion 4, the transistors P4, P5 and the transistor N5 are all turned off, and the transistor P6 is turned on, so that the supply of the operation current to the differential amplifier 2 is resumed and the output logic (drain potential of the transistor P3) of the differential amplifier 2 becomes variable in accordance with the input signal IN. As described above, by starting the differential amplifier 2 before the data update of the input signal IN, it becomes possible to suitably perform the on/off control of the differential amplifier 2 without causing trouble with the operation of the level shifter circuit. Here, it is sufficient to suitably set the start timing of the differential amplifier 2 considering the time required for the start of the differential amplifier 2.

When a time t2 arrives, the logic portion 20 updates the data of the input signal IN while changing the latch enable signal EN2 to the high level. Here, in the latch portion 5, the path switch SW1 is turned on and the output of the 3-state inverter INV6 is brought to a prohibition state (high impedance state), so that the output logic of the differential amplifier 2 is brought to a through-state (sampling state) to be output through the inverter INV5.

Thereafter, when a time t3 arrives, the logic portion 20, based on the recognition that the data of the input signal IN are invariable, keeps the amplifier enable signal EN1 and the latch enable signal EN2 at the low level. Accordingly, like in the state before the time t1, the differential amplifier 2 goes to a halt state; and in the latch portion 5, the output logic of the differential amplifier 2 goes to a state to be latched. Here, it is sufficient to suitably set the halt timing of the differential amplifier 2 considering the time required for the sample/hold operation of the latch portion 5.

As described above, according to the level shifter circuit according to the second embodiment, during a time (invariable-data time of the input signal IN) of the unused level shifter circuit, by interrupting the supply of the operation current to the differential amplifier 2, it is possible to hold the output logic of the differential amplifier 2 by means of the later-stage latch portion 5, so that it becomes possible to achieve reduction (e.g., ⅕ of the conventional) in the power consumption. Especially, it is possible to say that the level shifter circuit according to the second embodiment is suitably incorporated into an IC that is driven by a battery.

Besides, the liquid crystal drive device 12 according to the present embodiment, as shown in FIG. 5, has shared level shifter circuits 124a, 124b that by performing level shifting of the control signal pulse-driven between the positive potential VDDI and the ground potential VSS, generates the amplifier enable signal EN1 and the latch enable signal EN2 that are pulse-driven between the ground potential VSS and the negative potential MVDD and output these signals to the plurality of level shifter circuits. By employing such a structure, it becomes possible to curb the number of shared level shifter circuits 124a, 124b utilized that need to be always operated to a minimum.

FIG. 7 is a block diagram showing a second structural example of the liquid crystal display device that uses the level shifter circuit according to the present invention. As shown in FIG. 7, the liquid crystal display device (or, applications such as a mobile phone terminal and the like that incorporate the liquid crystal display device) has: a liquid crystal display panel A1; a multiplexer A2; a source driver circuit A3; a gate driver circuit A4; an external DC/DC converter A5; an MPU (Micro Processing Unit) A6; and an image source A7.

The liquid crystal display panel A1 is a TFT (Thin Film Transistor)-type image output means that uses a liquid crystal element, as a pixel, whose light transmittance changes in accordance with a voltage value of display data (analog voltage signal) that is supplied via the multiplexer A2 from the source driver circuit A3.

The multiplexer A2, based on a timing signal input from the source driver circuit A3, distributes each of n-system display data output from the source driver circuit A3 to z systems (z is 1 or a larger integer number), thereby generating (n×z)-system display data and supplying the data to the liquid crystal display panel A1.

The source driver circuit A3 converts the digital form of display data input from the image source A7 into the analog form of display data (analog voltage signal) and supplies the data to each pixel (more accurately, a source terminal of an active element connected to each pixel of the liquid crystal display panel A1) via the multiplexer A2. Besides, the source driver circuit A3 includes: a function to receive input of a command and the like from the MPU A6; a function to supply electric power to each portion (multiplexer A2 and the like) of the liquid crystal display device; a function to perform the timing control of each portion (multiplexer A2, gate driver circuit A4, and external DC/DC converter A5) of the liquid crystal display device; and a function to supply a common voltage to the liquid crystal display panel A1.

The gate driver circuit A4, based on the timing signal input from the source driver circuit A3, performs vertical scan control of the liquid crystal display panel A1.

The external DC/DC converter A5, based on the timing signal input from the source driver circuit A3, generates a power-supply voltage necessary for the drive of the gate driver circuit A4.

The MPU A6 is a main body that performs comprehensive control of an entire set in which the liquid crystal display device is incorporated, and supplies various commands, a clock signal, simple display data used in an 8-color display mode and the like to the source driver circuit A3.

The image source A7 supplies display data and a clock signal that are used in a usual display mode to the source driver circuit A3.

FIG. 8 is a block diagram showing a structural example of the source driver circuit A3. As shown in FIG. 8, the source driver circuit A3 in the present structural example has: an MPU interface B1; a command decoder B2; a data register B3; a partial display data RAM (Random Access Memory) B4; a data control portion B5; a display data interface B6; an image process portion B7; a data latch portion B8; a source driver portion B9; an OTPROM (One Time Programmable Read Only Memory) B10; a control register B11; an address counter (RAM controller) B12; a timing generator B13; an oscillator B14; a common voltage generation portion B15; a multiplexer timing generator B16; a gate driver timing generator B17; an external DC/DC timing generator B18; and a power-supply circuit B19 for the liquid crystal display device.

The MPU interface B1 performs communication of various commands, a clock signal, simple display data used in the 8-color display mode and the like with the MPU A6.

The command decoder B2 applies decode processing to the command and the simple display data obtained via the MPU interface B1.

The data register B3 temporarily stores various set data obtained via the MPU interface B1 and initial set data read from the OTPROM B10.

The partial display data RAM B4 is used as a storage for the simple display data.

The data control portion B5 performs read control of the simple display data stored in the partial display data RAM B4.

The display data interface B6 performs communication of display data and a clock signal that are used in the usual display mode with the image source A7.

The image process portion B7 applies predetermined image processing (brightness dynamic range correction, color correction, various noise removal correction and the like) to the display data input via the display data interface B6.

The data latch portion B8 latches the display data input via the image process portion B7, or, the simple display data input via the data control portion B5.

The source driver portion B9 performs drive control of the liquid crystal display panel A1 based on the display data or the simple display data that is input via the data latch portion B8.

The OTPROM B10 stores the initial set data to be stored in the data register B3 in a non-volatile way. Here, it is possible to write data into the OTPROM B10 only one time.

The control register B11 temporarily stores the command, the simple display data and the like obtained by the command decoder B2.

The address counter B12, based on the timing signal generated by the timing generator B13, reads the simple display data temporarily stored in the control register B11 and writes the data into the partial display data RAM B4.

The timing generator B13, based on an internal clock signal input from the oscillator B14, generates a timing signal necessary for synchronous control of the entire liquid crystal display device and supplies the timing signal to each portion (the data latch portion B8, the address counter B12, the common voltage generation portion B15, the multiplexer timing generator B16, the gate driver timing generator B17, the external DC/DC timing generator B18, and the power-supply circuit B19 for the liquid crystal display device) of the source driver circuit A3.

The oscillator B14 generates an internal clock signal that has a predetermined frequency and supplies the internal clock signal to the timing generator B13.

The common voltage generation portion B15, based on the timing signal input from the timing generator B13, generates a common voltage and supplies the common voltage to the liquid crystal display panel A1.

The multiplexer timing generator B16, based on the timing signal input from the timing generator B13, generates a timing signal for a multiplexer and supplies the timing signal to the multiplexer A2.

The gate driver timing generator B17, based on the timing signal input from the timing generator B13, generates a timing signal for a gate driver and supplies the timing signal to the gate driver circuit A4.

The external DC/DC timing generator B18, based on the timing signal input from the timing generator B13, generates a timing signal for external DC/DC and supplies the timing signal to the external DC/DC converter A5.

The power-supply circuit B19 for the liquid crystal display device, based on the timing signal input from the timing generator B13, generates a power-supply voltage for the liquid crystal display device and supplies the voltage to each portion (multiplexer A2 and the like) of the liquid crystal display device.

FIG. 9 is a block diagram showing a structural example of the source driver portion B9. As shown in FIG. 9, the source driver circuit 9 in the present structural example, in driving the liquid crystal display panel A1, performs polarity inversion control of an output signal applied to the liquid crystal element, and has: level shifter circuits C1(1) to C1(n); digital/analog conversion circuits C2(1) to C2(n); source amplifier circuits C3(1) to C3(n); path switches C4(1) to C4(n) for polarity inversion control; path switches C5(1) to C5(n) for the 8-color display mode; output terminals C6(1) to C6(n); a resistor ladder C7; selectors C8 to C11; amplifiers C12 to C15; a first gradation-voltage generation portion C16; a second gradation-voltage generation portion C17; and output capacitors C18 to C21.

Each of the level shifter circuits C1(1) to C1(n) performs level shifting of m-bit display data input from the data latch portion B8 and transmits the data to a later stage. Specifically, the level shifter circuit C1(i) (i=1, 3, 5, . . . , (n-1), which applies to the following as well) in an odd-number line is a positive-polarity level shifter circuit that converts an input signal into an output signal pulse-driven between a ground potential and a positive potential. On the other hand, the level shifter circuit C1(j) (j=(i+1)=2, 4, 6, . . . , n, which applies to the following as well) in an even-number line is a negative-polarity level shifter circuit that converts an input signal into an output signal pulse-driven between a ground potential and a negative potential. Here, each of the level shifter circuits C1(1) to C1(n) is composed of m level shifter circuits connected in parallel with each other to make it possible to receive m-bit display data in parallel. Besides, it is possible to apply the circuit structure according to the present invention described in the above FIG. 2 and FIG. 3 to the negative-polarity level shifter circuit C1(j).

Each of the digital/analog conversion circuits C2(1) to C2(n) converts the m-bit display data input via the level shifter circuits C1(1) to C1(n) and outputs the data.

More specifically, the digital/analog conversion circuit C2(i) in an odd-number line is driven between a ground potential and a positive potential and converts the digital form of display data into the analog form of display data (positive-polarity voltage). Here, a first gradation voltage (positive polarity) of 2^{m} gradations is input into the digital/analog conversion circuit C2(i) from the first gradation voltage generation portion C16. In other words, the analog form of display data generated by the digital/analog conversion circuit C2(i) is any one of the first gradation voltages (positive polarity) of 2^{m} gradations that is selected in accordance with the digital form of display data (m bits) input from the level shifter circuit C1(i)

On the other hand, the digital/analog conversion circuit C2(j) in an even-number line is driven between a ground potential and a negative potential and converts the digital form of display data into the analog form of display data (negative-polarity voltage). Here, a second gradation voltage (negative polarity) of 2^{m} gradations is input into the digital/analog conversion circuit C2(j) from the second gradation voltage generation portion C17. In other words, the analog form of display data generated by the digital/analog conversion circuit C2(j) is any one of the first gradation voltages of 2^{m} gradations that is selected in accordance with the digital form of display data (m bits) input from the level shifter circuit C1(j)

The source amplifier circuits C3(1) to C3(n) amplify the analog form of display data generated by the digital/analog conversion circuits C2(1) to C2(n) and outputs the amplified data to a later stage. More specifically, the source amplifier circuit C3(i) in an odd-number line is driven between a ground potential and a positive potential, increases an electric-current capability of the display data (positive-polarity signal) input from the digital/analog conversion circuit C2(i) and outputs the display data to a later stage. On the other hand, the source amplifier circuit C3(j) in an even-number line is driven between a ground potential and a negative potential, increases an electric-current capability of the display data (negative-polarity signal) input from the digital/analog conversion circuit C2(j) and outputs the display data to a later stage.

The path switches C4(1) to C4(n) for polarity inversion control change connection relationships between the source amplifier circuits C3(i) and C3(j) and the output terminals C6(i) and C6(j) in such a way that the output terminal C6(i) and the output terminal C6(j) adjacent to each other share a pair of each of the positive-polarity circuits (C1(i) to C3(i)) and each of the negative-polarity circuits (C1(j) to C3(j)).

For example, in a first frame, so as to connect the source amplifier circuit C3(i) and the output terminal C6(i) with each other and connect the source amplifier C3(j) and the output terminal C6(j) with each other, on/off control of the path switches C4(1) to C4(n) for polarity inversion control is performed. According to such switching control, in the first frame, as the output signal output to the liquid crystal element from the output terminal C6(i) in the odd-number line, the positive-polarity analog signal generated by the source amplifier C3(i) in the odd-number line is selected while as the output signal output to the liquid crystal element from the output terminal C6(j) in the even-number line, the negative-polarity analog signal generated by the source amplifier C3(j) in the even-number line is selected.

Next, in a second frame that follows the first frame, so as to connect the source amplifier circuit C3(i) and the output terminal C6(j) with each other and connect the source amplifier C3(j) and the output terminal C6(i) with each other, the on/off control of the path switches C4(1) to C4(n) for polarity inversion control is performed. According to such switching control, in the second frame, as the output signal output to the liquid crystal element from the output terminal C6(i) in the odd-number line, the negative-polarity analog signal generated by the source amplifier C3(j) in the even-number line is selected while as the output signal output to the liquid crystal element from the output terminal C6(j) in the even-number line is, the positive-polarity analog signal generated by the source amplifier C3(i) in the odd-number line is selected.

According to the structure that performs such polarity inversion control, a unidirectional voltage is not continuously applied to the liquid crystal element, so that it becomes possible to curb deterioration of the liquid crystal element.

Besides, according to the structure that performs the above polarity inversion control, it is possible to fix the common voltage (voltage applied in common to the opposite electrodes of all the liquid crystal elements) of the liquid crystal display panel A1 at the ground potential, so that it becomes unnecessary to charge and discharge an opposite capacitance of the liquid crystal display panel A1 and possible to achieve reduction in the power consumption.

Besides, according to the structure that performs the above polarity inversion control, the output terminal C6(i) and the output terminal C6(j) adjacent each other are able to share a pair of each of the positive-polarity circuits (C1(i) to C3(i)) and each of the negative-polarity circuits (C1(j) to C3(j)), it becomes possible to contribute to size reduction (chip-area reduction) of the source driver circuit A3.

The path switches C5(1) to C5(n) for the 8-color display mode, during a time of the 8-color display mode (operation mode in which image display is performed based on the simple display data input from the MPU A6), are used to output, from the output terminals C6(1) to C6(n), binary voltages that have the high level/low level only instead of the gradation voltages of 2^{m} gradations. Specifically, the path switch C5(i) for the 8-color display mode in an odd-number line has: a first path switch connected between the output terminal of the source amplifier C3(i) and the application terminal of the positive potential; and a second path switch connected between the output terminal of the source amplifier C3(i) and the application terminal of the ground potential; and so as to output either of the positive potential and the ground potential based on the simple display data, on/off control of the first and second path switches is exclusively (in a complementary way) performed. Besides, the path switch C5(j) for the 8-color display mode in an even-number line has: a third path switch connected between the output terminal of the source amplifier C3(j) and the application terminal of the negative potential; and a fourth path switch connected between the output terminal of the source amplifier C3(j) and the application terminal of the ground potential; and so as to output either of the negative potential and the ground potential is output based on the simple display data, on/off control of the third and fourth path switches is exclusively (in a complementary way) performed. Here, during the time of the 8-color display mode, the electricity supply to the level shifter circuits C1(1) to C1(n), the digital/analog conversion circuits C2(1) to C2(n), and the source amplifier circuits C3(1) to C3(n) is interrupted and each operation is halted. According to such a structure, it becomes possible to reduce unnecessary power consumption during the time of the 8-color display mode.

The output terminals C6(1) to C6(n) are external terminals for supplying the n-system output signals to the multiplexer A2 from the source driver circuit A3.

The resistor ladder C7 applies resistance division to a predetermined reference voltage (Vref), thereby generating a plurality of divided voltages.

Each of the selectors C8 to C11 selects any one of the plurality of divided voltages that are generated by the resistor ladder C7. Here, the divided voltage selected by the selector C8 and the divided voltage selected by the selector C9 have voltage values different from each other. Besides, the divided voltage selected by the selector C10 and the divided voltage selected by the selector C11 also have voltage values different from each other.

The amplifiers C12 and C13 both are driven between the ground potential and the positive potential, thereby amplifying the respective divided voltages input from the selectors C8 and C9 and generating first and second positive-polarity amplified voltages. The amplifiers C14 and C15 both are driven between the ground potential and the negative potential, thereby amplifying the respective divided voltages input from the selectors C10 and C11 and generating third and fourth negative-polarity amplified voltages.

The first gradation voltage generation portion C16 generates a first gradation voltage (positive polarity) of 2^{m} gradations that discretely changes between the first positive-polarity amplified voltage input from the amplifier C12 and the second positive-polarity amplified voltage input from the amplifier C13.

The second gradation voltage generation portion C17 generates a second gradation voltage (negative polarity) of 2^{m} gradations that discretely changes between the third negative-polarity amplified voltage input from the amplifier C14 and the fourth negative-polarity amplified voltage input from the amplifier C15.

The output capacitors C18 to C21 are connected to the output terminals of the amplifiers C12 to C15 respectively to smooth the first to fourth amplified voltages.

FIG. 10A and FIG. 10B are schematic diagrams that show a first connection outlook and a second connection outlook of the liquid crystal display panel A1 and the source driver circuit A3, respectively. Here, in FIG. 10A and FIG. 10B, for simple description, the representation of the multiplexer A2 is omitted. As shown in both figures, the source driver circuit A3, to deal with wiring selection of two types, has a function to change an output sequence of a source signal in accordance with a wiring state.

More specifically, in a wiring state in FIG. 10A, from an output terminal disposed between a long-edge central portion of the source driver circuit A3 and one long-edge end portion (upper end portion on the paper surface) of the source driver circuit A3, source signals S0/S1 for the 0-th/1st lines of the liquid crystal display panel A1, . . . , and source signals S236/S237 for the 236th/237th lines of the liquid crystal display panel A1 are successively output; and from an output terminal disposed between the long-edge central portion of the source driver circuit A3 and the other long-edge end portion (lower end portion on the paper surface) of the source driver circuit A3, source signals S2/S3 for the 2nd/3rd lines of the liquid crystal display panel A1, . . . , and source signals S238/S239 for the 238th/239th lines of liquid crystal display panel A1 are successively output. In other words, in the wiring state in FIG. 10A, the source signals are alternately successively distributed to both sides with respect to the long-edge central portion of the source driver circuit A3.

On the other hand, in a wiring state in FIG. 10B, from the output terminal disposed between the long-edge central portion of the source driver circuit A3 and one long-edge end portion (upper end portion on the paper surface) of the source driver circuit A3, the source signals S0/S1 for the 0-th/1st lines of the liquid crystal display panel A1, . . . , and source signals S118/S119 for the 118th/119th lines of the liquid crystal display panel A1 are successively output; and from the output terminal disposed between the long-edge central portion of the source driver circuit A3 and the other long-edge end portion (lower end portion on the paper surface) of the source driver circuit A3, source signals S120/S121 for the 120th/121st lines of the liquid crystal display panel A1, . . . , and the source signals S238/S239 for the 238th/239th lines of the liquid crystal display panel A1 are successively output. In other words, in the wiring state in FIG. 10A, the first half of the source signals are successively distributed to one long-edge end portion side and the second half of the source signals are successively distributed to the other long-edge end portion side with respect to the long-edge central portion of the source driver circuit A3.

According to the source driver circuit A3 having such an output sequence change function, it is possible to perform flexible wiring selection in accordance with users' needs.

FIG. 11 is a block diagram for describing timing control of the source driver circuit A3. As shown in FIG. 11, the source driver circuit A3 has: a oscillator D1; a timing generator D2; a display data interface D3; an address counter (RAM controller) D4; a partial display data RAM D5; a source data timing controller D6; an OTPROM D7; an OTP controller D8; an external DC/DC timing generator D9; a multiplexer gate driver timing generator D10; and a power-supply circuit D11 for the liquid crystal display panel. Here, in FIG. 11, for convenience of description, new reference numbers are attached to the function blocks as well already shown in FIG. 8.

The oscillator D1 (which corresponds to the oscillator B14 in FIG. 7) generates an internal clock signal that has a predetermined frequency and supplies the internal clock signal to the timing generator D2.

The timing generator D2 (which corresponds to the timing generator B13 in FIG. 7), based on the internal clock signal input from the oscillator D1 or the external clock signal input via the display data interface D3, generates a timing signal necessary for the synchronous control of the entire liquid crystal display device and supplies the timing signal to each portion (the address counter D4, the source data timing controller D6, the OTP controller D8, the external DC/DC timing generator D9, the multiplexer gate driver timing generator D10, and the power-supply circuit D11 for the liquid crystal display device) of the source driver circuit A3.

The display data interface D3 (which corresponds to the display data interface B6 in FIG. 7) performs communication of display data and a clock signal that are used in the usual display mode with the image source A7. Besides, the display data interface D3 supplies the external clock signal input from the image source A7 to the timing generator D2.

The address counter D4 (which corresponds to the address counter B12 in FIG. 7), based on the timing signal generated by the timing generator D2, reads the simple display data temporarily stored in the control register (not shown in FIG. 11) and writes the data into the partial display data RAM D5.

The partial display data RAM D5 (which corresponds to the partial display data RAM B4 in FIG. 8) is used as a storage for the simple display data.

The source data timing controller D6 (which corresponds to the data control portion B5 and the data latch portion B8 in FIG. 7), based on the timing signal generated by the timing generator D2, performs latch output of the display data input from the display data interface D3 or the simple display data stored in the partial display data RAM D5 to the source driver portion (not shown in FIG. 11).

The OTPROM D7 (which corresponds to the OTPROM B10 in FIG. 7) stores the initial set data to be stored in the data register (not shown in FIG. 11) in a non-volatile way. Here, it is possible to write data into the OTPROM D7 only one time.

The OTP controller D8, based on the timing signal generated by the timing generator D2, performs access control to the OTPROM D7.

The external DC/DC timing generator D9 (which corresponds to the external DC/DC timing generator B18 in FIG. 7), based on the timing signal input from the timing generator D2, generates a timing signal for external DC/DC and supplies the timing signal to the external DC/DC converter A5.

The multiplexer gate driver timing generator D10 (which corresponds to the multiplexer timing generator B16 and the gate driver timing generator B17 in FIG. 7), based on the timing signal input from the timing generator D2, generates a timing signal for a multiplexer and a timing signal for a gate driver, and supplies the timing signals to the multiplexer A2 and the gate driver circuit A4, respectively.

The power-supply circuit D11 (which corresponds to the power-supply circuit B19 for the liquid crystal display device in FIG. 7) for the liquid crystal display device, based on the timing signal input from the timing generator D2, generates a power-supply voltage for the liquid crystal display device and supplies the voltage to each portion (multiplexer A2 and the like) of the liquid crystal display device.

FIG. 12 is a table showing an example of an oscillation characteristic. As shown in this figure, the oscillation frequency fosc1 of the internal clock signal generated by the oscillator D1 is secured with 5 MHz (typ.).

Next, the 8-color display mode of the source driver circuit A3 is described. FIG. 13A and FIG. 13B are timing charts that show a first operation example and a second operation example of the 8-color display mode, respectively; and in order from the top, a chip select signal SCE, a reset signal RESX, a data signal SDI, and a clock signal SCL are represented

In a 3-line-9-bit serial interface mode, every time a 9-bit data signal SDI is input, data for 2 pixels is stored into a frame memory. Here, the contents of the data signal SDI are: a data/command specification flag (“1” is data, “0” is a command) in the head 1 bit; empty data in the next 2 bits; x-th pixel data (R, G, B) in the next 3 bits; and (x+1)-th pixel data (R, G, B) in the next 3 bits. However, in a case where the last pixel that forms a frame ends at an odd number, the data of the last pixel is transmitted as shown in FIG. 13B. In other words, the contents of the data signal SDI are: the data/command specification flag in the head 1 bit; the empty data in the next 2 bits; and the x-th (last) pixel data (R, G, B) in the next 3 bits; and the next 3-bit pixel data is neglected. Here, the above 3-bit pixel data is used for the switching control of the path switches C5(1) to C5(n) for the 8-color display mode shown in FIG. 9.

Next, reset operation of the source driver circuit A3 is described. As reset methods of the source driver circuit A3, two kinds of methods of a hardware reset and a software reset are prepared. In the hardware reset, initialization is performed in accordance with a voltage level at a RESX terminal. When the RESX terminal is brought to a low level, irrespective of an operation state in the inside of the source driver circuit A3, the source driver circuit A3 is immediately brought to a reset state. In the software reset, the initialization is performed by issuance of a software reset command. When the software reset command is recognized, if the operation state of the source driver circuit A3 is “display ON,” the source driver circuit A3 is brought to the reset state after an automatic display off sequence is executed. On the other hand, if the operation state of the source driver circuit A3 is “display OFF,” the source driver circuit A3 is immediately brought to the reset state.

Differences between the hardware reset and the software reset are summed up in FIG. 14 to FIG. 16. FIG. 14 is a table for describing the reset methods. FIG. 15 is a table for describing a state after the reset. FIG. 16 is a table for describing the automatic display off sequence.

Here, in the above description, the example, in which the level shifter circuit according to the present invention is applied to the liquid crystal display device (especially, the liquid crystal drive device that is incorporated in the liquid crystal display device), is described; however, the structure of the present invention is not limited to this, and the present invention is widely applicable to all level shifter circuits that are used for other applications.

Besides, it is possible to make various modifications to the structure of the present invention without departing from the spirit of the present invention.

### INDUSTRIAL APPLICABILITY

The present invention is a technology useful for reduction in the number of high breakdown-voltage elements that form a level shifter circuit; and for example, is a preferred technology for a liquid crystal drive device in which many level shifter circuits have to be confined and disposed in a width-wise length of a liquid crystal panel.

### REFERENCE SIGNS LIST

[10] glass board

[11] liquid crystal pixel

[12] liquid crystal drive device

[121] level shifter circuit group

[122] digital/analog conversion circuit group

[123] source amplifier circuit group

[124a, 124b] shared level shifter circuits

[20] logic portion

[30] flexible cable

[1] input buffer

[2] differential amplifier

[3] output buffer

[4] enable control portion

[5] latch portion

[N1, N2] N-channel MOS field effect transistors (high breakdown-voltage elements)

[N3 to N5] N-channel MOS field effect transistors (intermediate breakdown-voltage elements)

[P1 to P6] P-channel MOS field effect transistors (intermediate breakdown-voltage elements)

[INV1, INV1] inverters (low breakdown-voltage elements)

[INV3 to INV5] inverters (intermediate breakdown-voltage elements)

[INV6] 3-state inverter (intermediate breakdown-voltage elements)

[SW1] path switch (intermediate breakdown-voltage element)

[A1] liquid crystal display panel (liquid crystal pixel)

[A2] multiplexer

[A3] source driver circuit

[A4] gate driver circuit

[A5] external DC/DC converter

[A6] MPU

[A7] image source

[B1] MPU interface

[B2] command decoder

[B3] data register

[B4] partial display data RAM

[B5] data control portion

[B6] display data interface

[B7] image process portion

[B8] data latch portion

[B9] source driver portion

[B10] OTPROM

[B11] control register

[B12] address counter (RAM controller)

[B13] timing generator

[B14] oscillator

[B15] common voltage generation portion

[B16] multiplexer timing generator

[B17] gate driver timing generator

[B18] external DC/DC timing generator

[B19] power-supply circuit for liquid crystal display device

[C1(1) to C1(n)] level shifter circuits

[C2(1) to C2(n)] digital/analog conversion circuits

[C3(1) to C3(n)] source amplifier circuits

[C4(1) to C4(n)] path switches (for polarity inversion control)

[C5(1) to C5(n)] path switches (for 8-color display mode)

[C6(1) to C6(n)] output terminals

[C7] resistor ladder

[C8 to C11] selectors

[C12 to C15] amplifiers

[C16] first gradation voltage generation portion (positive polarity)

[C17] second gradation voltage generation portion (negative polarity)

[C18 to C21] output capacitors

[D1] oscillator

[D2] timing generator

[D3] display data interface

[D4] address counter (RAM controller)

[D5] partial display data RAM

[D6] source data timing controller

[D7] OTPROM

[D8] OTP controller

[D9] external DC/DC timing generator

[D10] multiplexer gate driver timing generator

[D11] power-supply circuit for liquid crystal display device

1. A level shifter circuit comprising:
a differential amplifier comprising a differential input stage which includes a pair of N-channel field effect transistors connected between an application terminal of a ground potential and an application terminal of a negative potential, wherein the differential amplifier is arranged to receive a differential input signal that is pulse-driven between the ground potential and a positive potential, and to apply differential amplification to the input signal, thereby generating an output signal that is pulse-driven between the ground potential and the negative potential.

2. The level shifter circuit according to claim 1, wherein of a plurality of transistors that form the level shifter circuit, the pair of N-channel field effect transistors that form the differential input stage are high breakdown-voltage elements that are able to endure a potential difference between the positive potential and the negative potential; and the other transistors are intermediate breakdown-voltage elements and low breakdown-voltage elements that have a lower breakdown voltage.

3. The level shifter circuit according to claim 2, further comprising:
an enable control portion that turns on/off the differential amplifier in accordance with a first control signal; and
a latch output portion that sample-holds the output signal of the differential amplifier in accordance with a second control signal.

4. A load drive device comprising n (n is 1 or a larger integer number) sets of units each of which includes:
m level shifter circuits that perform level shifting of each of m-system (m is 2 or a larger integer number) input signals to generate m-system output signals;
a digital/analog conversion circuit that receives the m-system output signals as an m-bit digital signal, converts the m-bit digital signal into an analog signal and outputs the analog signal; and
an amplifier circuit that supplies the analog signal as a load drive signal to the load;
wherein of the plurality of level shifter circuits, a level shifter circuit that converts an input signal pulse-driven between a ground potential and a positive potential into an output signal pulse-driven between the ground potential and a negative potential is the level shifter circuit according to claim 3.

5. The load drive device according to claim 4, further comprising:
a shared level shifter circuit that generates first and second control signals that are pulse-driven between the ground potential and the negative potential, wherein the shared level shifter circuit outputs these signals to the plurality of level shifter circuits.

6. The load drive device according to claim 5, wherein the load is a liquid crystal pixel.

7. A liquid crystal display device comprising:
the load drive device according to claim 6;
wherein the liquid crystal pixel is driven by the load drive device.

8. A liquid crystal display device according to claim 7 comprising:
a multiplexer arranged to distribute each of n-system output signals output from the load drive device to z systems (z is 1 or a larger integer number), and to generate (n×z)-system output signals and supply these signals to the liquid crystal pixel.

9. The liquid crystal display device according to claim 8, wherein the load drive device includes a multiplexer timing generator that performs timing control of the multiplexer in accordance with generation operation of the n-system output signals.
